(19) United States
(12) Patent Application Publication
(10) Pub. No.: US 2019/0369190 A1
(43) Pub. Date: Dec. 5, 2019

(54) METHOD FOR PROCESSING INTERIOR COMPUTED TOMOGRAPHY IMAGE USING ARTIFICIAL NEURAL NETWORK AND APPARATUS THEREFOR

(71) Applicant: Korea Advanced Institute of Science and Technology, Daejeon (KR)

(72) Inventors: JongChul Ye, Daejeon (KR); Yoseob Han, Daejeon (KR)

(73) Assignee: Korea Advanced Institute of Science and Technology, Daejeon (KR)

(21) Appl. No.: 16/431,608

(22) Filed: Jun. 4, 2019

(30) Foreign Application Priority Data
Jun. 4, 2018 (KR) 10-2018-0064261

(51) Int. Cl. G01R 33/56; G06N 3/08; G06N 20/10; G06T 11/00

(52) U.S. Cl. CPC G01R 33/56; G06N 3/08; G06T 2211/40; G06T 11/003; G06N 20/10

(57) ABSTRACT

A method for processing an interior computed tomography image using an artificial neural network and an apparatus therefor are disclosed. The method includes receiving magnetic resonance image (MRI) data, and reconstructing an image for the MRI data using a neural network interpolating a K-space.

### CROSS-REFERENCE TO RELATED APPLICATIONS

This application claims priority under 35 U.S.C. § 119 to Korean Patent Application No. 10-2018-0064261 filed on Jun. 4, 2018, in the Korean Intellectual Property Office, the disclosures of which are incorporated by reference herein in their entireties.

### BACKGROUND

Embodiments of the inventive concept described herein relate to a method for processing a magnetic resonance image (MRI) and an apparatus therefore, and more particularly to a method for processing an image and an apparatus therefore, capable of reconstructing an MRI to a high-quality image by using a neural network for interpolating a k-space.

A magnetic resonance image (MRI) device is a representative medical image device capable of acquiring a thermography image together with a computed tomography (CT). Particularly, the MRI device acquires k-space coefficient corresponding to a tomography image in an image space and then transform the k-space coefficients to image space coefficients through an inverse Fourier operator. However, it takes a long time to acquire the k-space coefficients, so examinees may feel uncomfortable. Especially, the examinees may move within the period of acquiring the k-space coefficients, which distorts the k-space coefficients. In the end, noise is made in a tomography image, so image quality may be degraded. To overcome the above disadvantage, the period of acquiring the k-space coefficient by sparsely acquiring the k-space coefficients and then an iterative reconstruction scheme based on unacquired information is performed, thereby reconstructing the tomography image.

Recently, researchers inspired by the success of deep learning in classification and low-level computer vision problems have investigated deep learning techniques for a variety of biomedical image reconstruction problems and have demonstrated significant performance improvements. In MR literature, the studies and researches applying deep learning have first been with respect to MRI (CS-MRI). The deep learning reconstruction was used either as an initialization or a regularization term. According to a conventional technology, deep network architecture using unfolded iterative compressed sensing (CS) algorithm was proposed. According to the relevant technology, the attempts were made to learn a set of regulating devices under a variable framework instead of using a handcrafted regulating device. Multilayer perceptron was introduced into accelerated parallel MRI. According to the technology, novel extension was made using deep residual learning, domain adaptation, data consistency layers, and cyclic consistency. An extreme form of the neural network called AUtomated TransfOrm by Manifold APproximation (AUTOMAP) estimated the Fourier transform itself using fully connected layers. All these convention studies show excellent reconstruction performances at significantly lower run-time computational complexity rather than the compressed sensing approaches. In spite of such performance improvement by deep learning techniques for reconstruction problems, the theoretical origin of the success is hardly understood. According to most prevailing explanations, a deep network is interpreted as unrolled iterative steps based on variation optimization framework, or regarded as a generative model or an abstract form of manifold learning. However, none of the techniques completely find out the blackbox characteristic of the deep network. For example, complete solutions are not made to MR-related questions such as the optimal manner of processing complex-valued MR data set, the role of the nonlinearity such as rectified linear unit (ReLU) for the complex-valued data, and the number of required channels.

The biggest issue for MR community is that the link to the classical MR image reconstruction technique is still not completely understood. For example, compressed sensing (CS) theories have been extensively studied to reconstruct an MR image reconstruction based on under-sampled k-space samples by applying sparsity. The structured low-rank matrix completion algorithms were suggested as the latest algorithms in CS-MRI to improve performance. In particular, an annihilating filter-based low-rank Hankel matrix approach (ALOHA) changes a CS-MRI problem to a k-space interpolation problem by using the sparsity. However, there is no deep learning algorithm to directly interpolate missing k-space data in a completely data-based manner.

FIGS. 1A and 1B illustrate MRI reconstruction using the most typical neural network, in which the MRI reconstruction is based on a scheme of learning in an image space in the form of performing post-processing in an image domain or the form of performing iterative updates between a k-space and the image domain through a cascaded network. In other words, since the acquired k-space coefficient is not reflected, the MRI reconstruction is similar to post-processing image reconstruction. In addition, FIG. 1C illustrates a neural network of directly reconstructing a tomography image from the k-space coefficient. The neural network is called AUtomated TransfOrm by Manifold APproximation (AUTOMAP). Although an end-to-end reconstruction scheme like AUTOMAP may directly reconstruct the image without interpolating missing k-space samples. In this case, the required memory size may be determined by multiplying the number of samples in a k-space multiplied by the number of image domain pixels.

### SUMMARY

Embodiments of the inventive concepts provide a method for processing an image and an apparatus therefore, capable of reconstructing an MRI image to a high-quality image by using a neural network for interpolating a k-space.

In detail, embodiments of the inventive concepts provide a method for processing an image and an apparatus therefore, capable of reconstructing an MRI image to a high-quality image as a tomography image is acquired by interpolating non-acquired k-space coefficients using a neural network and by transforming the k-space coefficients to image space coefficients through inverse Fourier inverse.

According to an exemplary embodiment, a method for processing an image includes receiving magnetic resonance image (MRI) data, and reconstructing an image for the MRI data using a neural network to interpolate a k-space.

Further, according to an embodiment, the method may further include regridding for the received MRI data. The reconstructing of the image may include reconstructing the image for the MRI data by interpolating a k-space of the reground MRI data using the neural network.

The reconstructing of the image may include reconstructing the image for the MRI data using a neural network satisfying a preset low-rank Hankel matrix constraint.

The reconstructing of the image may include reconstructing the image for the MRI data using a neural network of a model trained through residual learning.

The neural network may include a neural network based on an annihilating filter-based low-rank Hankel matrix approach (ALOHA) and a neural network based on a deep convolutional framelet.

The neural network may include a neural network based on a convolution framelet.

The neural network may include a multi-resolution neural network including a pooling layer and an unpooling layer, and may include a bypass connection from the pooling layer to the unpooling layer.

According to another exemplary embodiment, a method for processing an image may include receiving MRI data, and reconstructing an image for the MRI data using a neural network based on an annihilating filter-based low-rank Hankel matrix approach (ALOHA) and a neural network based on a deep convolutional framelet.

According to another exemplary embodiment, an apparatus for processing an image includes a receiving unit to receive MRI data, and a reconstructing unit to reconstruct an image for the MRI data using a neural network to interpolate a k-space.

The reconstructing unit may perform regridding for the received MRI data, and may reconstruct the image for the MRI data by interpolating a k-space of the reground MRI data using the neural network.

The reconstructing unit may reconstruct the image for the MRI data using a neural network satisfying a preset low-rank Hankel matrix constraint.

The reconstructing unit may reconstruct the image for the MRI data using a neural network of a model trained through residual learning.

The neural network may include a neural network based on an annihilating filter-based low-rank Hankel matrix approach (ALOHA) and a neural network based on a deep convolutional framelet.

The neural network may include a neural network based on a convolution framelet.

The neural network may include a multi-resolution neural network including a pooling layer and an unpooling layer, and may include a bypass connection from the pooling layer to the unpooling layer.

As described above, according to an embodiment of the inventive concept, k-space coefficients, which are not acquired, are interpolated using a neural network, and transformed into image space coefficients through an inverse Fourier operation to acquire the tomography image, thereby reconstructing the magnetic resonance image to the high-quality tomography image.

According to an embodiment of the inventive concept, since only the minimum memory is required when the neural network operation is performed, the operation may be sufficiently performed even with the resolution of the magnetic resonance image. The uncertainty about the manipulation of the complex data format which is difficult to deal with in an MRI and the definition of a rectified linear unit (ReLU) and the channel, which are commonly used in the neural network are described, so the neural network may directly perform the interpolation in a Fourier space.

According to an embodiment of the inventive concept, in the technology of reconstructing the MRI by acquiring down-sampled k-space coefficients, down-sampling patterns include Cartesian patterns and non-Cartesian patterns such as radial and spiral patterns, and reconstruction performance may be improved with respect to all the down-sampling patterns. In other words, according to the inventive concept, the down-sampled k-space is interpolated and the distortions (for example, herringbone, zipper, ghost, DC artifacts, or the like) of the k-space coefficient, such as the distortion caused by the movement of the patient or the distortion caused by the MRI device, may be compensated.

Conventionally, studies and researches have been performed by mainly using iterative reconstruction methods to interpolate the down-sampled k-space or to compensate for the distorted k-space coefficient. However, in the case of the iterative reconstruction methods, it takes a long time for reconstruction, it is difficult to apply the iterative reconstruction methods to a medical device. In addition, the commercialization of the iterative reconstruction methods is difficult. According to the inventive concept, the reconstruction time may be significantly reduced by reconstructing an image using the neural network. In addition, as the excellent reconstruction performance is represented, excellent marketability may be represented. Particularly, in the case of the MRI, since it takes a long time to capture the MRI, it is difficult to capture MRIs for many patients a day. However, according to the inventive concept, since the time to capture the MRI may be significantly reduced, the number of patients for the MRIs may be significantly increased. Accordingly, the patients may be photographed within a shorter time of period and may be more rapidly examined. In addition, doctors using MRI devices may create the large number of profits as the number of MRIs captured a day is increased.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates deep learning frameworks for accelerated MRI;

FIG. 2 is a flowchart illustrating a method for processing an MRI, according to an embodiment of the inventive concept;

FIG. 3 illustrates neural networks based on the ALOHA and the deep convolution framelet;

FIG. 4 illustrates the structure of a deep learning network structure for an MRI;

FIG. 5 illustrates the comparison in reconstruction results from Cartesian trajectory between the method according to the inventive concept and the conventional method;

FIG. 6 illustrates the comparison in reconstruction results from radial trajectory between the method according to the inventive concept and the conventional method;

FIG. 7 illustrates the comparison in reconstruction results from spiral trajectory between the method according to the inventive concept and the conventional method; and

FIG. 8 is a view illustrating the configuration of an MRI processing device, according to an embodiment of the inventive concept.

### DETAILED DESCRIPTION

Advantage points and features of the inventive concept and a method of accomplishing thereof will become apparent from the following description with reference to the following figures, wherein embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. The inventive concept may be defined by scope of the claims. Meanwhile, the terminology used herein to describe embodiments of the invention is not intended to limit the scope of the inventive concept.

The terms used in the inventive concept are provided for the illustrative purpose, but the inventive concept is not limited thereto. As used herein, the singular terms “a,” “an” and “the” are intended to include the plural forms as well, unless the context clearly indicates otherwise. Furthermore, it will be further understood that the terms “comprises”, “comprising,” “includes” and/or “including”, when used herein, specify the presence of stated components, steps, operations, and/or devices, but do not preclude the presence or addition of one or more other components, steps, operations and/or devices.

Unless otherwise defined, all terms (including technical and scientific terms) used herein have the same meaning as commonly understood by those skilled in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the inventive concept will be described in more detail with reference to accompanying drawings. The same reference numerals are used with respect to the same elements on drawings, and the redundant details of the same elements will be omitted.

According to embodiments of the inventive concept, the subject matter thereof is to reconstruct a magnetic resonance image into a high-quality image using a neural network to interpolate a Fourier space.

In this case, according to the inventive concept, unacquired k-space coefficients may be interpolated using neural networks and transformed into inverse image space coefficients through inverse Fourier transform to obtain the tomographic image.

Further, in the network of the inventive concept, an additional regridding layer is simply added and easily applied to a non-Cartesian k-space track.

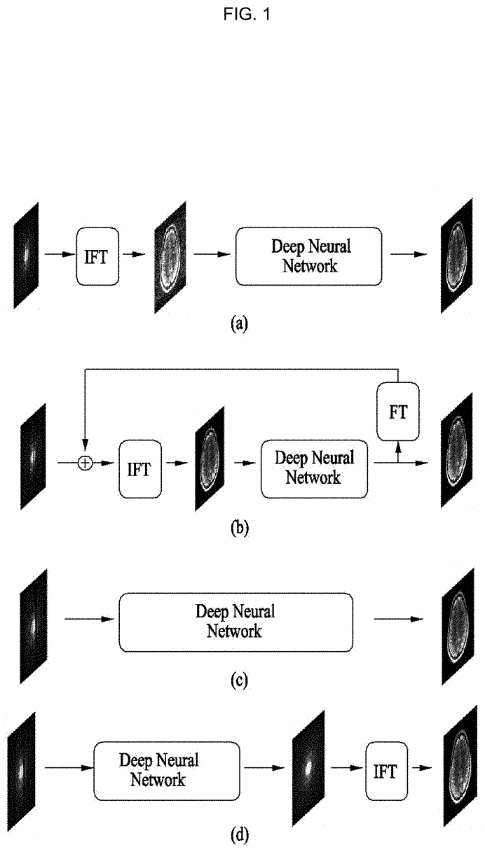

In the neural network of the inventive concept, as illustrated in FIG. 1D, the unacquired k-space coefficients are directly interpolated through the neural network, and transformed into image space coefficients through inverse Fourier inverse, thereby acquiring the tomography image. In other words, according to the deep learning scheme of the inventive concept, since missing k-space data is directly interpolated, it is possible to exactly acquire reconstruction, the Fourier transform may be simply performed with respect to the k-space data, thereby exactly performing reconstruction.

Recently, according to the recent convolution framelet theory, an encoder-decoder network emerges from the data-centered low-rank Hankel matrix decomposition, and this rank structure is controlled by the number of filter channels. This discovery provides an important clue for developing a successful deep learning technique for k-space interpolation. According to the inventive concept, the deep learning technique for k-space interpolation is to process a typical k-space sampling pattern in addition to Cartesian trajectory such as radial or spiral trajectories. In addition, all networks are implemented in the form of a convolution neural network which does not require a completely connected layer, and required GPU memory may be minimized.

The neural network employed in the inventive concept may include a convolution framelet-based neural network, and may include multi-resolution neural networks including a pooling layer and an unpooling layer. Further, a multi-resolution neural network may include a bypass connection from the pooling layer to the un-pooling layer.

The above-described convolution framelet is expressed by using a local basis and a non-local basis for an input signal, and the details thereof will be described as follows.

The convolution framelet, which is expressed by using the local basis ψⱼ and the non-local basis ϕᵢ for an input signal ‘f’, and may be expressed as following Equation 1.

$$f = \frac{1}{d} {\sum }_{i = 1}^{n} {\sum }_{j = 1}^{q} 〈 f , {φ}_{i} {ψ}_{j} 〉 {\tilde{φ}}_{i} {\tilde{ψ}}_{j} \qquad Equation 1$$

In Equation 1, ϕᵢ refers to linear transformation having the non-local basis, and ψⱼ may refer to linear transformation having the local basis vector.

In this case, the local and non-local basis vectors may have dual basis vectors \tilde{ϕ}ᵢ and \tilde{ψ}ⱼ orthogonal to each other, and the orthogonal relation between basis vectors may be defined as following Equation 2.

$$\tilde{Φ} {Φ}^{⊤} = {\sum }_{i = 1}^{m} {\tilde{φ}}_{i} {φ}_{i}^{⊤} = {I}_{n \times n} , Ψ {\tilde{Ψ}}^{⊤} = {\sum }_{j = 1}^{q} {ψ}_{j} {\tilde{ψ}}_{j}^{⊤} = {I}_{d \times d} \qquad Equation 2$$

When Equation 2 is used, the convolution framelet may be expressed as following Equation 3.

[symbol]

_{d}(f)=\acute{Φ}Φ^{T} [symbol] _{d}(f)Ψ\tilde{Ψ}^{T}=\tilde{Φ}C\tilde{Ψ}^{T}

C=Φ^{T} [symbol] _{d}(f)Ψ=Φ^{T}(f\textcircled{*}Ψ) Equation 3

In this case, H_{d} may refer to a Hankel matrix operator, which may express a convolution operation to matrix multiplication. C may refer to a convolution framelet coefficient which is a signal converted based on the local basis and the non-local basis.

The convolution frame coefficient C may be reconstructed to an original signal by applying a dual basis vector \tilde{ϕ}ᵢ, \tilde{ψ}ⱼ. The signal reconstruction process may be expressed as following Equation 4.

f=(\tilde{Φ}C)\textcircled{*}τ(\tilde{Ψ}) Equation 4

As described above, a scheme of expressing an input signal through the local basis and the non-local basis may be called “convolution framelet”.

### Notations

In the inventive concept, the matrix is expressed in bold uppercase letters, for example, A and B, and the vector is expressed in bold lowercase letters, for example, x and y. Besides, [A]ᵢⱼ denote (i,j)^{th} element of matrix A, and [x]ⱼ denotes an j^{th} element of vector x. Notation v̅ϵ [symbol] ^{p} for vector vϵ [symbol] ^{d} refers to a flipped version, which means that the indexes of the vector V are reversed. Identify matrix N×N is expressed as I_{N}, and 1_{N} refers to an N-dimensional vector of 1. Superscripts ‘T’ and T for_the matrix or vector denotes a transpose and Hermitian transpose. [symbol] and [symbol] refer to real number and imaginary number fields, and [symbol] + refers to a real number having no negative number.

### Forward Model for Accelerated MRI)

The spatial Fourier transform of an arbitrary smooth function x: [symbol] ²→ [symbol] may be defined as following Equation 5.

\hat{x}(k)= [symbol] [x](k):= [symbol] e^{-ik·r}x(r)dr Equation 5

In this case, kϵ [symbol] ² denotes a spatial frequency, and may be i=\sqrt{−1}.

When {kₙ}ₙ₌₁^{N} is called a collection of finite numbers of sampling points in k-space that verify the Nyquist sampling rate, with respect to a certain integer Nϵ [symbol] , the discretized k-space data xϵ [symbol] ^{N} may be expressed as in Equation 6 as follows.

\hat{x}=[\hat{x}(k₁) . . . \hat{x}(k_{N})]′ Equation 6

A down sampling operator [symbol] _{Λ}: [symbol] ^{N}→ [symbol] ^{N} for an under sampling pattern Λ given for acquiring accelerated MRI may be defined as following Equation 7.

$${[ {𝒫}_{Λ} [ \hat{x} ] ]}_{j} = \{ \begin{matrix}{[ \hat{x} ]}_{j} j ∈ Λ \\ 0 , otherwise\end{matrix} \qquad Equation 7$$

Under-sampled k-space data may be expressed as in Equation 8.

ŷ:= [symbol] _{Λ}[\hat{x}] Equation 8

### ALOHA

A CS-MRI attempts to find a feasible solution having minimal non-zero support in a sparsifying transform domain. This may be performed by finding the smooth function z: [symbol] ²→ [symbol] as following Equation 9.

$${min}_{z} {‖ {}_{z} ‖}_{1} \\ subject to {𝒫}_{Λ} [ \hat{x} ] = {𝒫}_{Λ} [ \hat{z} ] \qquad Equation 9$$

In this case, [symbol] may refer to an image domain sparsifying transform, and \hat{z} may be expressed as following Equation 10.

\hat{z}=[ [symbol] (k₁) . . . [symbol] (k_{N})]′ Equation 10

This optimization problem requires repeated updates between the k-space and the image domain after the discretization of [symbol] (r).

In ALOHA, although the image domain sparsifying transform is performed through an existing CS-MRI algorithm, the ALOHA is interested in direct k-space interpolation unlike the CS-MRI scheme. In more detail, when [symbol] _{d}(\hat{x}) is a Hankel matrix formed from k-space measurement \hat{X}, d may denote a matrix pencil size. According to the ALOHA theory, in an image domain, an underlying signal x(r) is a finite rate of innovations (FRI) having sparsification and the rate of ‘s’, and the rank the related Hankel matrix [symbol] _{d}(\hat{x}) having d>8 is lowered.

Accordingly, when a portion of k-space data is omitted, an appropriate weighted Hankel matrix having omitted elements may be constructed such that the omitted elements are recovered through a lower-rank Hankel completion scheme as following Equation 11.

$$( P ) {min}_{\hat{z} ∈ {ℂ}^{N}} RANK {ℍ}_{d} ( \hat{z} ) \\ subject to {𝒫}_{Λ} [ \hat{x} ] = {𝒫}_{Λ} [ \hat{z} ] \qquad Equation 11$$

The issues of the rower weighted Hankel matrix may be solved through various manners, and the ALOHAT may employ matrix factorization approaches.

ALOHA is very useful for MR artifact correction as well as accelerated MR acquisition and may be used for many low-level computer vision problems. However, the main technical confusion is the relatively large operational complexity for matrix factorization and the memory requirements to store the Hankel matrix. Although several new techniques have been proposed to solve these problems, the deep-running technique is a new and efficient way to solve the problem by making the matrix decomposition completely data-centric and expressive.

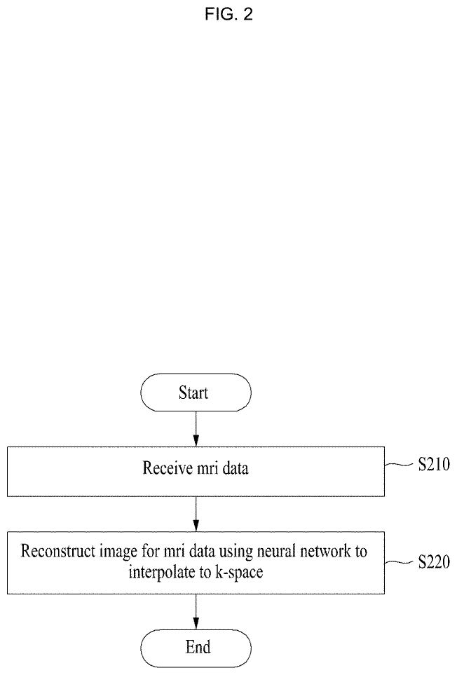

FIG. 2 is a flowchart illustrating a method of processing an MRI, according to an embodiment of the inventive concept.

Referring to FIG. 2, according to an embodiment of the inventive concept, the method of processing the MRI includes receiving MRI data (S210) and reconstructing the image for MRI data using a neural network interpolating a k-space (S220).

In this case, operation S220 is to reconstruct the image for the MRI data using the neural network of a model trained through residual learning.

Further, in operation S220, the image for the MRI data may be reconstructed by a neural network satisfying a present low-rank Hankel matrix constraint.

Further, in operation S220, after performing regridding for the MRI data, the k-space of the MRI data subject to regridding is interpolated by using the neural network, thereby reconstructing the image for the MRI.

According to the inventive concept, the neural network may include a convolution framelet-based neural network, and in detail, may include a multi-resolution neural network including a pooling layer and an unpooling layer.

In this case, the convolutional framelet may refer to a scheme of expressing an input signal using a local basis and a non-local basis.

Furthermore, the neural network may include a bypass connection from the pooling layer to the unpooling layer.

According to the inventive concept, the sparsity of the signal represents the low-rankness in a Hankel matrix for a signal in a dual space through the ALOHA scheme in terms of compressed sensing-based signal reconstruction. The basis function of the Hankel matrix may be decomposed, through the deep convolution framelet theory, into a local basis function and a global basis function, which serve as a convolution function and a pooling function of the neural network, respectively.

As described above, according to the inventive concept, the neural network may include a neural network based on an annihilating filter-based low-rank Hankel matrix approach (ALOHA) and a neural network based on a deep convolutional framelet.

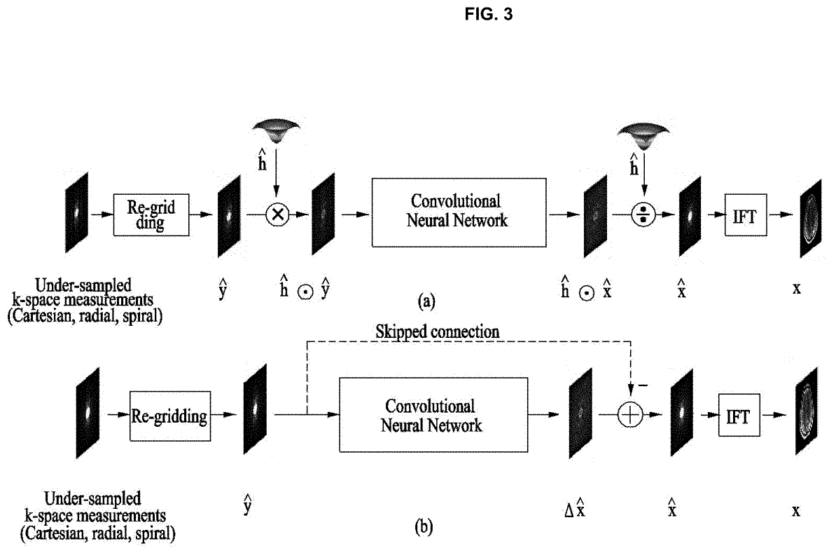

FIG. 3 illustrates neural networks based on the ALOHA and the deep convolution framelet, which illustrates two neural network structures depending on schemes of ensuring the sparsity of the signal.

As illustrated in FIG. 3, according to an embodiment of the inventive concept, the neural network includes weighting (a) performed in compression sensing-based operation and residual learning (b) using skipped connection performed in a neural network.

Hereinafter, the above methods according to the inventive concept will be described with reference to FIGS. 3 to 7.

ALOHA with Learned Low-Rank Basis

Image regression is considered under a low-rank Hankel matrix constraint as Equation 12.

[symbol]

_{Λ}[\hat{x}]= [symbol] _{Λ}[\hat{z}] Equation 12

In Equation 12, ‘s’ may refer to the estimated rank.

The cost expressed in the first line of Equation 12 may be defined as an image domain for minimizing an error in the image domain, and the low-rank Hankel matrix constraints expressed in the second and third lines of Equation 12 may be applied a k-space after k-space weighting.

According to the inventive concept, to find a link for the deep learning technique implemented in the real number domain, the complex value constraint of Equation 12 is converted into a real value constraint. Accordingly, the operator [symbol] : [symbol] ^{N}→ [symbol] ^{N×2} may be defined as following Equation 13.

[symbol]

[\hat{z}]:=[Re(\hat{z})Im(\hat{z})],∀\hat{z}ϵ [symbol] ^{N} Equation 13

In this case, Re( ) and Im( ) may refer to real and imaginary parts.

Identically, according to the inventive concept, an inverse operator [symbol] ⁻¹: [symbol] ^{N×2}→ [symbol] ^{N} of Equation 13 may be defined as following Equation 13.

[symbol]

⁻¹[Z]:=\hat{z}₁+i\hat{z}₂,∀Z:=[z₁z₂]ϵ [symbol] ^{N×2} Equation 14

In this case, if RANK [symbol] _{d}(\hat{z})=8, the expression may be made as Equation 15.

=RANK [symbol] _{d|2}( [symbol] [\hat{z}])≤2s Equation 15

Accordingly, Equation 12 may be changed to an optimization problem having a real value constraint, and may be expressed as following Equation 16.

[symbol]

_{Λ}[\hat{x}]= [symbol] _{Λ}[\hat{z}] Equation 16

Although the optimization problem having a low-rank constraint is solved through a singular value shrinkage and Matrix Factorization, one of the most important finding in the deep convolution framelet is to solve the problem by using learning-based signal expression.

In more detail, if Hankel structured matrix [symbol] _{d|2} ( [symbol] [\hat{z}]) has a single value composition UΣV^{T} with respect to a certain zϵ [symbol] ^{N}, U=[u₁ . . . u_{Q}]ϵ [symbol] ^{N×Q} and V=[v₁ . . . v_{Q}]ϵ [symbol] ^{2d×Q} refer to a left single vector basis matrix and a right single vector basis matrix, and Σ=(σᵢⱼ)ϵ [symbol] ^{Q×Q} refers to a diagonal matrix having single values. When considering a matrix pair Ψ, \tilde{Ψ}ϵ [symbol] ^{2d×Q} satisfying the low rank projection constraint, the matrix pair can be expressed as illustrated in following Equation 17, and the low rank projection constraint can be expressed as following Equation 18.

$$\begin{matrix}Ψ := ( \begin{matrix}{ψ}_{1}^{1} … {ψ}_{Q}^{1} \\ {ψ}_{1}^{2} … {ψ}_{Q}^{2}\end{matrix} ) and \tilde{Ψ} := ( \begin{matrix}{\tilde{ψ}}_{1}^{1} … {\tilde{ψ}}_{Q}^{1} \\ {\tilde{ψ}}_{1}^{2} … {\tilde{ψ}}_{Q}^{2}\end{matrix} ) & Equation 17 \\ Ψ {\hat{Ψ}}^{⊤} = {P}_{R ( V )} & Equation 18\end{matrix}$$

In this case, P_{R(V)} may refer to a projection for the space having the range of V.

The inventive concept uses a generalized pooling matrix and an unpooling matrix Ψ, \tilde{Ψ}ϵ [symbol] ^{N×M} satisfying the following Equation 19.

\tilde{Ψ}Ψ^{T}=P_{R(U)} Equation 19.

A matrix equality such as following Equation 20 may be obtained by using Equations 18 and 19.

[symbol]

_{d|2}( [symbol] [\hat{z}])=\tilde{Ψ}Ψ^{T} [symbol] _{d|2}( [symbol] [\hat{z}])Ψ\tilde{Ψ}^{T}=\tilde{Φ}C\tilde{Ψ}^{T} Equation 20

In Equation 20, C:=Φ^{T} [symbol] _{d|2}( [symbol] [\hat{z}])Ψϵ [symbol] ^{N×Q}.

By taking the generalized inverse matrix of the Hanckel matrix, Equation 20 may be transformed as a framelet basis representation having the framelet coefficient C. In addition, the frame-based representation in Equation 20 may be equivalently expressed by a single-layer encoder-decoder convolutional architecture and may be expressed as following Equation 21.

C=Φ^{T}( [symbol] [\hat{z}]\textcircled{*}Ψ̅), [symbol] [\hat{z}]=(\tilde{Φ}C)\textcircled{*}ν(\tilde{Ψ}) Equation 21

In this case, \textcircled{*} denotes the multi-channel input multi-channel output convolution.

The first and the second part of Equation 21 correspond to the encoder and decoder lavers having the corresponding convolution filters Ψ̅ϵ [symbol] ^{2d×Q} and ν(\tilde{Ψ}⁽ⁱ⁾)ϵ [symbol] ^{dQ×2}, respectively. The corresponding convolution filters may be expressed as following Equation 22.

$$\overline{Ψ} := ( \begin{matrix}{\overline{ψ}}_{1}^{1} … {\overline{ψ}}_{Q}^{1} \\ {\overline{ψ}}_{1}^{2} … {\overline{ψ}}_{Q}^{2}\end{matrix} ) , v ( \tilde{Ψ} ) := ( \begin{matrix}{\tilde{ψ}}_{1}^{1} & {\tilde{ψ}}_{1}^{2} \\ ⋮ & ⋮ \\ {\tilde{ψ}}_{Q}^{1} & {\tilde{ψ}}_{Q}^{2}\end{matrix} ) \qquad Equation 22$$

The corresponding convolution filters are obtained by reordering the matrices Ψ and \tilde{Ψ} in Equation 17. Specifically, ψ̅ᵢ¹ϵ [symbol] ^{d} (resp. ψ̅ᵢ²ϵ [symbol] ^{d}) denotes the d-tap encoder convolutional filter applied to the real (resp. imaginary) component of the k-space data to generate the i-^{th} channel output. In addition, \dot{ν}(\tilde{Ψ}) is a re-ordered version of \tilde{Ψ} so that and \tilde{ψ}ᵢ¹ϵ [symbol] ^{d} (resp. \tilde{ψ}ᵢ²ϵ [symbol] ^{d}) denotes the d-tap decoder convolutional filter to generate the real (resp. imaginary) component of the k-space data by convolving with the i-^{th} channel input.

Equation 21 is as follows. First, the k-space data \hat{Z} are split into two channels with the real and imaginary components, respectively. Then, the encoder filters generate Q-channel outputs from this two channel inputs using multi-channel convolution, after which the pooling pooling operation defined by Φ^{T} is applied to each Q-channel output. The resulting Q-channel feature maps correspond to the convolutional framelet coefficients. At the decoder, the Q-channel feature maps are processed using unpooling layer represented by \tilde{Φ}, which are then convoluted with the decoder filters to generate real and image channels of the estimated k-space data. Finally, complex valued k-space data are formed from the two channel outputs. The rank structure of the estimated Hankel matrix is fixed with the number of filter channels, that is. Q.

Since Equation 21 is a general form of the signals that are associated with a rank-Q Hankel structured matrix, Equation 21 is used to estimate bases for k-space interpolation. To this end, the filters Ψ, \tilde{Ψ}ϵ [symbol] ^{2d×Q} may be estimated from the training data. Specifically, the signal space H0, which is based on the convolutional framelet basis is considered, may be expressed as Equation 23.

[symbol]

⁰={Gϵ [symbol] ^{N×2}|G=Φ^{T}(C\textcircled{*}ν(\tilde{Ψ})),C=(\tilde{Φ}G)\textcircled{*}Ψ̅} Equation 23

The ALOHA formulation PA can be equivalently represented by follow Equation 24.

subject to [symbol] _{Λ}[\hat{x}]= [symbol] _{Λ}[\hat{z}] Equation 24

It is assumed that the training data set {ŷ₍ᵢ₎, x₍ᵢ₎}ᵢ₌₁^{M} is given. In this case, ŷ₍ᵢ₎ denotes the under-sampled k-space data and x₍ᵢ₎ refers to the corresponding ground-truth image. Then, the following filter estimation formulation as in Equation 25 may be obtained from (P′_{A}), of Equation 24.

$${min}_{Ψ , \overline{Ψ} ∈ {ℝ}^{2 d \times Q}} {\sum }_{i = 1}^{M} {‖ {x}_{( i )} - ( {\hat{y}}_{( i )} ; Ψ , \tilde{Ψ} ) ‖}^{2} \qquad Equation 25$$

In this case, the operator [symbol] : [symbol] ^{N}→ [symbol] ^{N} may be defined as expressed in follow Equation (26) in terms of mapping C: [symbol] ^{N×2}→ [symbol] ^{N×Q}, and C can be expressed as following Equation (27).

[symbol]

(ŷ₍ᵢ₎;Ψ,\tilde{Ψ})= [symbol] ⁻¹[ [symbol] ⁻¹[(\tilde{Φ}C( [symbol] [ŷ₍ᵢ₎]))\textcircled{*}ν(\tilde{Ψ})]] Equation 26

C(Ĝ)=Φ^{T}(Ĝ*Ψ̅),∀Ĝϵ [symbol] ^{N×2} Equation 27

After the network is fully trained, the image inference from a down-sampled k-space data ŷ is simply performed by [symbol] (ŷ; Ψ, \tilde{Ψ}), while the interpolated k-space samples can be obtained by following Equation 28.

\hat{z}= [symbol] ⁻¹[(\tilde{Φ}C( [symbol] [ŷ₍ᵢ₎]))\textcircled{*}ν(\tilde{Ψ})] Equation 28

### DeepALOHA

The inventive concept may be extended to a multi-layer deep convolutional framelet extension. In particular, it is assumed that the encoder and decoder convolution filters Ψ̅, ν(\tilde{Ψ})ϵ [symbol] ^{2d×Q} may be represented in the cascaded convolution of the small length filters as expressed in following Equation 29.

$$\overline{Ψ} = {\overline{Ψ}}^{( 0 )} … {\overline{ Ψ}}^{( j )} \\ v ( \tilde{Ψ} ) = v ( {\tilde{Ψ}}^{( J )} ) … v ( {\tilde{Ψ}}^{( 0 )} ) \\ {\overline{Ψ}}^{( j )} := ( \begin{matrix}{\overline{ψ}}_{1}^{1} & … & {\overline{ψ}}_{{Q}^{( 3 )}}^{1} \\ ⋮ & ⋱ & ⋮ \\ {\overline{ψ}}_{1}^{{p}^{( j )}} & … & {\overline{ψ}}_{{Q}^{( 3 )}}^{{P}^{( 3 )}}\end{matrix} ) \\ v ( {\tilde{Ψ}}^{( j )} ) := ( \begin{matrix}{\tilde{ψ}}_{1}^{1} & … & {\tilde{ψ}}_{1}^{p ( j )} \\ ⋮ & ⋱ & ⋮ \\ {\tilde{ψ}}_{{Q}^{( j )}}^{1} & … & {\tilde{ψ}}_{{Q}^{( j )}}^{{P}^{( j )}}\end{matrix} ) \qquad Equation 29$$

In this case, d(j), P(j), and Q(j) are the filter lengths, the number of input channels, and the number of output channels for the j-^{th} layer, respectively, which satisfies the condition of Equation 18 for the composite filter Ψ and \tilde{Ψ}.

Since the deep convolutional framelet expansion is a linear representation, the space H0 in Equation 23 is restricted so that the signal is present in the conic hull of the convolutional framelet basis to enable part-by-part representation similar to nonnegative matrix factorization (NMF), which is recursively defined as following Equation 30.

[symbol]

⁰={Gϵ [symbol] ^{N×2}|G=(\tilde{Φ}⁽⁰⁾C⁽⁰⁾\textcircled{*}ν(\tilde{Ψ}⁽⁰⁾), C⁽⁰⁾=Φ^{(0)T}(G\textcircled{*}Ψ̅⁽⁰⁾)ϵ [symbol] ¹, [C⁽⁰⁾]ₖₗ≥0,∀k,l}, Equation 30

In this case, [symbol] j, j=1, . . . , J−1 may be defined as following Equation 31.

[symbol]

^{j}={Aϵ [symbol] ^{N×P}^{^{(j)}}|A=(\tilde{Φ}^{(j)}C^{(j)}\textcircled{*}ν(\tilde{Ψ}^{(j)}), C^{(j)}=Φ^{(j)T}(A\textcircled{*}Ψ̅^{(j)})ϵ [symbol] ^{j+1}, [C^{(j)}]ₖₗ≥0,∀k,l}

[symbol]

^{J}= [symbol] ₊^{N×P}^{^{(L)}} Equation 31

This positivity constraint may be implemented using rectified linear unit (ReLU) during training. According to the inventive concept, the generalized version having ReLU and pooling layers are called as DeepALOHA.

### Sparsification

According to the inventive concept, to improve the performance of the structured matrix completion approach, even if the image x(r) may not be sparse, the image x(r) may be converted to an innovation signal using a shift-invariant transform represented by the whitening filter h such that the resulting innovation signal z=h*x becomes an FRI signal. For example, many MR images may be sparsified using finite difference. In this case, since \hat{z}(k)=ĥ(k)\hat{x}(k) is low-ranked, the Hankel matrix from the weighted k-space data is low-ranked. In this case, the weight \hat{ }h(k) is determined from the finite difference or Haar wavelet transform. Accordingly, after the deep neural network is applied to the weighted k-space data to estimate the missing spectral data ĥ(x)\hat{x}(k), the original k-space data is obtained by dividing with the same weight, that is, \hat{x}(k)=\hat{z}(k)/ĥ(k). In this case of the signal \hat{x}(k) at the spectral null of the filter ĥ(k), the corresponding elements may) be specifically obtained as sampled measurements, which may be easily performed in MR acquisition. Hereinafter, it is assumed that ĥ(kᵢ)≠0 for all i. In DeepALOHA, this can be easily implemented using a weighting and unweighting layer as illustrated in FIG. 3A.

Deep ALOHA allows another scheme to make the signal sparse. Fully sampled k-space data \hat{x} may be represented as following Equation 32.

\hat{x}=ŷ+Δ\hat{x} Equation 32

In this case, ŷ may denote the under-sampled k-space measurement in Equation 8, and Δ\hat{x} may denote the residual part of k-space data that is estimated.

In practice, some of the low-frequency part of k-space data including the DC component are acquired in the under-sampled measurement so that the image component from the residual k-space data Δ\hat{x} are high frequency signals, which are sparse. Therefore, Δ\hat{x} has low-rank Hankel matrix structure, which can be effectively processed using the deep neural network. This may be easily implemented using a skipped connection before the deep neural network as illustrated in FIG. 3B. These two sparsification schemes may be combined for further performance improvement.

### Overall Architecture

Since the Hankel matrix formulation in ALOHA implicitly assumes the Cartesian coordinate, additional regridding layers are added in front of the k-space weighting layer to deal with the non-Cartesian sampling trajectories. Particularly, for radial and spiral trajectories, the non-uniform fast Fourier transform (NUFFT) may be used to perform the regridding to Cartesian coordinates. For Cartesian sampling trajectories, the regridding layer using NUFFT is not necessary, and we instead perform the nearest neighborhood interpolation to initially fill in the unacquired k-space regions.

### Network Backbone

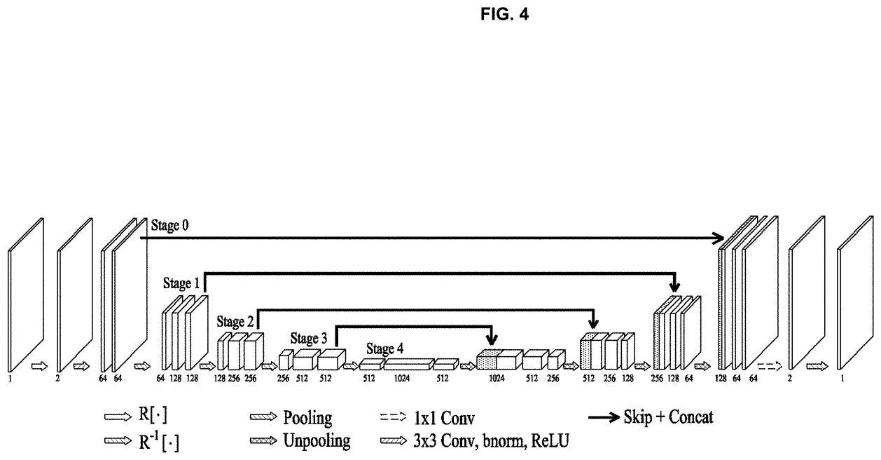

FIG. 4 illustrates a deep learning network structure for an MRI. As illustrated in FIG. 4, according to the U-Net structure, the deep learning network structure for the MRI includes a convolution layer to perform a linear transform operation, a batch normalization layer to perform a normalization operation, a rectified linear unit (ReLU) layer to perform a nonlinear function operation, and a contracting path connection with concatenation. In this case, the input and output are the complex-valued k-space data, and [symbol] [⋅] and [symbol] ⁻¹[⋅] illustrated in FIG. 4 denote an operators as in Equation 13 and Equation 14 of converting a complex valued input to two-channel value signals and vice versa. Each stage includes convolution, rectified linear unit (ReLU), and batch normalization layers and has the basic operator. The number of channels is increased to twice and the size of layers is decreased to four times after each pooling layer. In this case, the pooling layer may be a 2×2 average pooling layer and the unpooling layer may be 2×2 average unpooling layer. The pooling layer and the unpooling layer may be located between between the stages. A skip and concatenation layer (skip+Concat) may be a skip and concatenation operator. The convolution layer (1×1 Cony) having a 1×1 kernel may be a convolution operator to generate k-space data interpolated from multichannel data. The number of channels for each convolution layer is illustrated in FIG. 4.

In addition, the network illustrated in FIG. 4 uses the average pooling layer and the average unpooling layer as the non-local basis or transmits the signal of the input unit to the output unit through the bypass connection layer. The U-Net is recursively applied to a low-resolution signal. In this case, the input is filtered through a local convolution filter to be reduced to an approximate signal having the half size through the pooling operation. The bypass connection may compensate for a high frequency lost during pooling.

### Network Training

According to the inventive concept, the 12 loss is used in the image domain in (VA) for training. To this end, the Fourier transform operator is placed as the last layer to convert the interpolated k-space data to the complex-valued image domain so that the loss values are calculated for the reconstructed image. Stochastic gradient descent (SGD) optimizer was used to train the network according to the inventive concept. In the case of the IFT layer, the adjoint operation from SOD may be Fourier transform. The size of mini batch was 4, and the number of epochs was 300. The initial learning rate was 10⁻⁵ which gradually dropped to 10⁻⁶. The regularization parameter was λ=10⁻⁴.

The labels for the network may be the images generated from direct Fourier inversion from fully sampled k-space data. The input data for the network may be the regridded down-sampled k-space data from Cartesian, radial, and spiral trajectories. For each trajectory, the network may be separately trained. The network may be implemented using MatConvNet toolbox under MATT-AB R2015a environment.

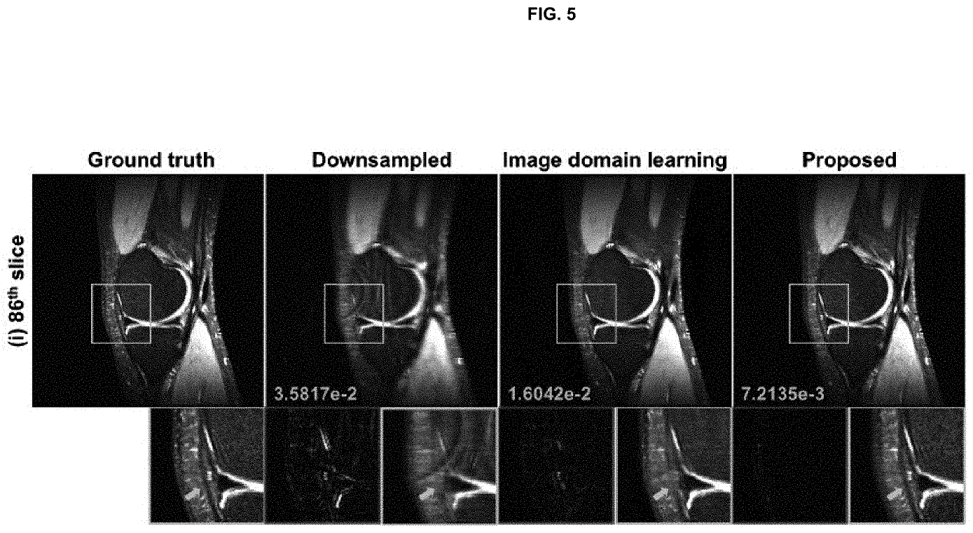

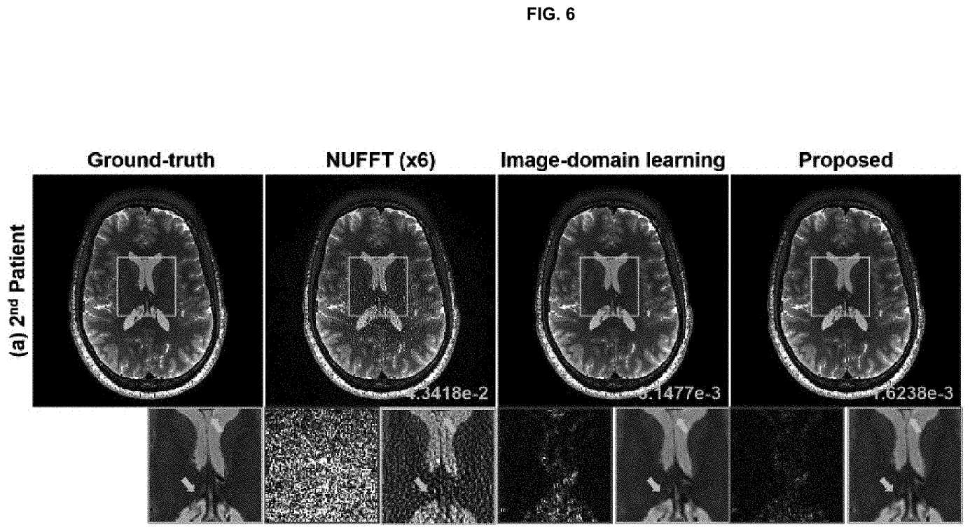

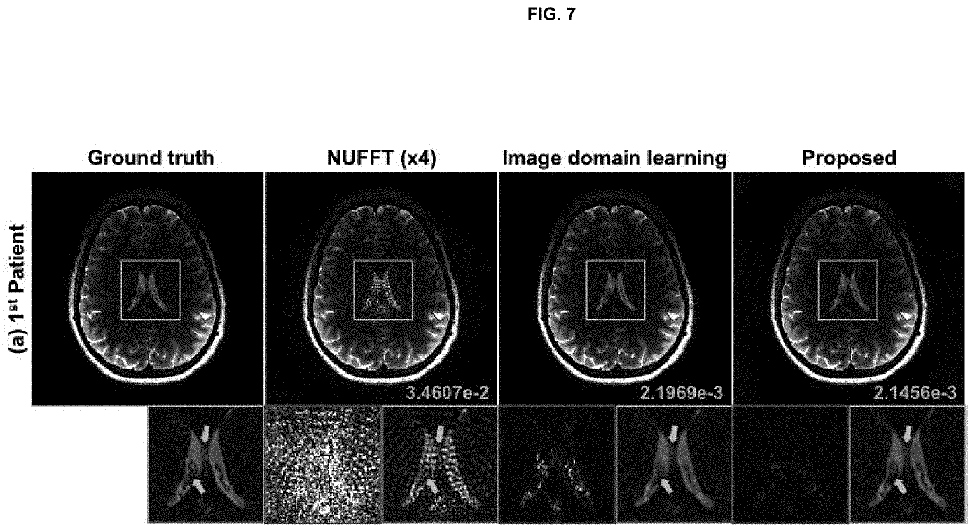

FIG. 5 illustrates the comparison in reconstruction results from Cartesian trajectory between the method according to the inventive concept and a conventional method. FIG. 6 illustrates the comparison in reconstruction results from radial trajectory between the method according to the inventive concept and a conventional method. FIG. 7 illustrates the comparison in reconstruction results from spiral trajectory between the method according to the inventive concept and a conventional method.

In this case, FIG. 5 is a view illustrating image results reconstructed from a Cartesian sample reduced by four times, FIG. 6 is a view illustrating image results reconstructed from a radial sample reduced by six times, and FIG. 7 is a view illustrating image results reconstructed from a spiral sample reduced by four times. From the left side of FIG. 5, an original image, a down-sampled image, an image domain learning reconstructed image, and a reconstructed image according to the inventive concept are sequentially illustrated. The left-side image among lower images shows the differential image between the original image and the reconstructed image, and the right-side image among lower images shows an image enlarged from a boxed region of an upper image. In addition, numbers written on the image represent a normalized mean squares error (NMSE).

As recognized from FIGS. 5 to 7, in the case of the reconstruction technique using the image spatial learning, there is a blurring phenomenon in the image, while a delicate structural form is lost. In contrast, according to the method of the inventive concept, a blurring phenomenon hardly appears while a real texture is being represented. Furthermore, since even a clue, which cannot be found in a down-sampled image, is directly interpolated in the K-space, the delicate structure may be clearly reconstructed. In addition, as recognized through the NMSE value, the NMSE value according to the method of the inventive concept is lower than the NMSE value according to the conventional method.

As described above, according to an embodiment of the inventive concept, k-space coefficients, which are not acquired, are interpolated using a neural network, and transformed into image space coefficients through an inverse Fourier operation to acquire the tomography image, thereby reconstructing the magnetic resonance image to the high-quality tomography image.

According to an embodiment of the inventive concept, since only the minimum memory is required when the neural network operation is performed, the operation may be sufficiently performed even with the resolution of the magnetic resonance image. The uncertainty about the manipulation of the complex data format which is difficult to deal with in an MRI and the definition of a rectified linear unit (ReLU) and the channel, which are commonly used in the neural network are described, so the neural network may directly perform the interpolation in a Fourier space.

According to an embodiment of the inventive concept, in the technology of reconstructing the MRI by acquiring down-sampled k-space coefficients, down-sampling patterns include Cartesian patterns and non-Cartesian patterns such as radial and spiral patterns, and reconstruction performance may be improved with respect to all the down-sampling patterns. In other words, according to the inventive concept, the down-sampled k-space is interpolated and the distortions (for example, herringbone, zipper, ghost, DC artifacts, or the like) of the k-space coefficient, such as the distortion caused by the movement of the patient or the distortion caused by the MRI device, may be compensated.

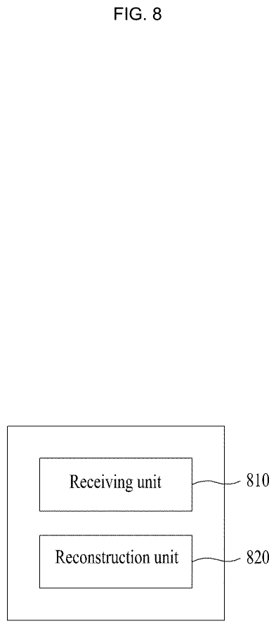

FIG. 8 is a view illustrating the configuration of an MRI processing device, according to an embodiment of the inventive concept, that is, the configuration of the device of performing the method of FIGS. 1 to 7.

Referring to FIG. 8, according to an embodiment of the inventive concept, the MRI processing device 800 includes a receiving unit 810 and a reconstruction unit 820.

The receiving unit 810 receives MRI data.

In this case, the receiving unit 810 may receive under-sampled MRI data.

The reconstructing unit 820 reconstructs an image for the MRI data by using a neural network of interpolating a K-space.

In this case, the reconstructing unit 820 may perform regrinding for the received MRI data, and the K-space of the regridded MRI data is interpolated by using the Neural network, so that the image for the MRI data may be reconstructed.

Further, the reconstructing unit 820 may reconstruct an image for the MRI data by using the neural network satisfying a preset low-rank Hankel matrix constraint.

Further, the reconstructing unit 820 may reconstruct the image for the MRIS data by using the neural network of the model trained through residual learning.

The neural network may include a neural network based on an annihilating filter-based low-rank Hankel matrix approach (ALOHA) and a neural network based on a deep convolutional framelet.

The neural network may include a neural network based on a convolution framelet.

The neural network may include a multi-resolution neural network including a pooling layer and an unpooling layer, and may include a bypass connection from the pooling layer to the unpooling layer.

Although the details are omitted in the description of the device illustrated in FIG. 8, components for the view of FIG. 7 may cover all description made with respect to FIGS. 1 to 7, which is obvious to those skilled in the art.

The foregoing devices may be realized by hardware elements, software elements and/or combinations thereof. For example, the devices and components illustrated in the exemplary embodiments of the inventive concept may be implemented in one or more general-use computers or special-purpose computers, such as a processor, a controller, an arithmetic logic unit (ALU), a digital signal processor, a microcomputer, a field programmable array (FPA), a programmable logic unit (PLU), a microprocessor or any device which may execute instructions and respond. A processing unit may perform an operating system (OS) or one or software applications running on the OS. Further, the processing unit may access, store, manipulate, process and generate data in response to execution of software. It will be understood by those skilled in the art that although a single processing unit may be illustrated for convenience of understanding, the processing unit may include a plurality of processing elements and/or a plurality of types of processing elements. For example, the processing unit may include a plurality of processors or one processor and one controller. Also, the processing unit may have a different processing configuration, such as a parallel processor.

Software may include computer programs, codes, instructions or one or more combinations thereof and configure a processing unit to operate in a desired manner or independently or collectively control the processing unit. Software and/or data may be permanently or temporarily embodied in any type of machine, components, physical equipment, virtual equipment, computer storage media or units so as to be interpreted by the processing unit or to provide instructions or data to the processing unit. Software may be dispersed throughout computer systems connected via networks and be stored or executed in a dispersion manner. Software and data may be recorded in one or more computer-readable storage media.

The methods according to the above-described exemplary embodiments of the inventive concept may be recorded in computer-readable media including program instructions to implement various operations embodied by a computer. The computer-readable medium may also include the program instructions, data files, data structures, or a combination thereof. The program instructions recorded in the media may be designed and configured specially for the exemplary embodiments of the inventive concept or be known and available to those skilled in computer software. The computer-readable medium may include hardware devices, which are specially configured to store and execute program instructions, such as magnetic media, optical recording media (e.g., CD-ROM and DVD), magneto-optical media (e.g., a floptical disk), read only memories (ROMs), random access memories (RAMs), and flash memories. Examples of computer programs include not only machine language codes created by a compiler, but also high-level language codes that are capable of being executed by a computer by using an interpreter or the like.

While a few exemplary embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

What is claimed is:

1. A method for processing an image, the method comprising:
receiving magnetic resonance image (MRI) data; and
reconstructing an image for the MRI data using a neural network to interpolate a K-space.

2. The method of claim 1, further comprising:
regridding for the received MRI data,
wherein the reconstructing of the image includes:
reconstructing the image for the MRI data by interpolating a K-space of the reground MRI data using the neural network.

3. The method of claim 1, wherein the reconstructing of the image includes:
reconstructing the image for the MRI data using a neural network satisfying a preset low-rank Hankel matrix constraint.

4. The method of claim 1, wherein the reconstructing of the image includes:
reconstructing the image for the MRI data using a neural network of a model trained through residual learning.

5. The method of claim 1, wherein the neural network includes:
a neural network based on an annihilating filter-based low-rank Hankel matrix approach (ALOHA) and a neural network based on a deep convolutional framelet.

6. The method of claim 1, wherein the neural network includes a neural network based on a convolution framelet.

7. The method of claim 1, wherein the neural network includes:
a multi-resolution neural network including a pooling layer and an unpooling layer.

8. The method of claim 7, wherein the neural network includes:
a bypass connection from the pooling layer to the unpooling layer.

9. A method for processing an image, the method includes:
receiving MRI data; and
reconstructing an image for the MRI data using a neural network based on an annihilating filter-based low-rank Hankel matrix approach (ALOHA) and a neural network based on a deep convolutional framelet.

10. An apparatus for processing an image, the apparatus comprising:
a receiving unit to receive MRI data; and
a reconstructing unit to reconstruct an image for the MRI data using a neural network to interpolate a k-space.

11. The apparatus of claim 10, wherein the reconstructing unit performs regridding for the received MRI data, and reconstructs the image for the MRI data by interpolating a K-space of the reground MRI data using the neural network.

12. The apparatus of claim 10, wherein the reconstructing unit reconstructs the image for the MRI data using a neural network satisfying a preset low-rank Hankel matrix constraint.

13. The apparatus of claim 10, wherein the reconstructing unit reconstructs the image for the MRI data using a neural network of a model trained through residual learning.

14. The apparatus of claim 10, wherein the neural network includes:
a neural network based on an annihilating filter-based low-rank Hankel matrix approach (ALOHA) and a neural network based on a deep convolutional framelet.

15. The apparatus of claim 10, wherein the neural network includes a neural network based on a convolution framelet.

16. The apparatus of claim 10, wherein the neural network includes:
a multi-resolution neural network including a pooling layer and an unpooling layer.

17. The apparatus of claim 16, wherein the neural network includes:
a bypass connection from the pooling layer to the unpooling layer.
